(19) United States
(12) Patent Application Publication
(10) Pub. No.: US 2005/0266904 A1
(43) Pub. Date: Dec. 1, 2005

(54) Antenna control method, and wireless transmission and reception device

(75) Inventors: Mitsuhiro Kitaji, Yokohama-shi (JP); Takashi Matsumura, Yokohama-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/131,083

(22) Filed: May 17, 2005

(30) Foreign Application Priority Data
May 31, 2004 (JP) P 2004-161508

(51) Int. Cl. H04B 1/44; H04B 1/02; H03C 7/02

(52) U.S. Cl. 455/575.7; 455/101; 455/78

(57) ABSTRACT

An antenna control method for use in communication using a plurality of antennas which have different respective frequency bands, has a step in which, when performing transmission upon a predetermined frequency band out of the frequency bands, only an antenna which corresponds to the frequency band which is used is employed in a transmission system, and a step in which, when performing reception upon the predetermined frequency band, a diversity combination of the antenna which corresponds to the predetermined frequency band which is used and another antenna is employed in a reception system.

### BACKGROUND OF THE INVENTION

1. Field of the Invention

The present invention relates to an antenna control method, and to a wireless transmission and reception device, which are used in a wireless communication terminal, or the like which has a reception diversity function.

Priority is claimed on Japanese Patent Application No. 2004-161508, filed May 31, 2004, the content of which is incorporated herein by reference.

2. Description of Related Art

With a wireless communication terminal of the cdma 2000 1x EV-DO type (hereinafter, which is termed the EV-DO type), the necessity for diversity is high, since the data rate of the downstream traffic channel is determined by the CIR (Carrier to Interference Ratio: which is also expressed as C/I) which indicates the state of reception. On the other hand, there are two wireless bands within Japan which can be used for EV-DO, one in the neighborhood of 800 MHz and another in the neighborhood of 2 GHz; but, in order to use these frequency bands with a single terminal, in other words, in order to build a dual band terminal, it is necessary to provide a transmission and reception circuit and an antenna corresponding to each of these bands, the circuitry becomes more complicated than in the case of a terminal which uses only one or the other of these frequency bands, and thereby the number of components becomes large and the cost increases. In particular, it is necessary to provide two (or more) antennas for diversity for each frequency, since an EV-DO terminal which has diversity corresponds to a plurality of frequency bands, and thereby problems arise in which the number of components, the cost, and the physical size of the unit are increased.

Therefore, a wireless communication device has been developed which is capable of receiving signals upon a plurality of frequency bands with a common antenna by the diversity method. This device is arranged to employ common antennas for PHS (Personal Handyphone System) and PDC (Personal Digital Cellular), and, as an example, two common antennas which correspond to a PDC of 1.5 GHz frequency band and a PHS of 1.9 GHz frequency band are used, and when communicating with either of these communication methods (PDC or PHS), it turns a transmission and reception circuit for the appropriate communication method ON (and turns the circuit for the other communication method OFF), by changing the transmission and reception circuit for the communication method which is to be used to the transmission and reception circuit which is the communication method receiving the antennas, and using the transmission and reception circuit, it possible to reduce the number of antennas which are required from four to two, while, by turning off the supply of power to the transmission and reception circuit which is used for the other communication method which is not used, a reduction of electrical power consumption can be attained (Japanese Unexamined Patent Application, First Publication No. H9-181660).

In general, in the case of comparing a dual band antenna or a multi-band antenna which has a plurality of resonant frequencies with a single band antenna which has a resonant frequency at a single frequency, when being viewed at each of frequency, the gain (transmission gain, efficiency) is low, moreover the characteristics as an antenna, such as the gain, the radiation characteristics, or the like, is different according to the frequency. Thereby, as compared with in the case of providing the reception diversity, and using two antennas for each of two frequency bands, which is a total of four antennas, reception performance is decreased in the case of using two antennas in common for the two frequency bands. Moreover, the same concept is applied for the case of transmitting a signal, due to the fact that the transmission gain (efficiency) is lowered, the output signal transmission power is lowered, or in particular, in the case of EV-DO, since increase and decrease of the output transmission power is instructed by the base station, it is necessary to supply a greater signal transmission electric power to the antenna in order to obtain the same output transmission power, and thereby there is a problem of an increase in electrical power consumption. On the other hand, in the case of using four antennas as described above, it is possible to obtain the most suitable performance as far as the efficiency of the antennas; however there are the problems in that the number of components, the cost, and the like are increased, and the physical size of the terminal becomes great (due to the increase in the number of the antennas).

In addition, in another prior technology, there is disclosed a reception circuit which employs two antennas which are provided corresponding to the two reception frequencies, and which receives signals upon selection diversity of one of the reception frequencies (Japanese Unexamined Patent Application, First Publication No. 2004-23536). However, the resonant frequencies of the two antennas are different, and, if the gain of one of the antennas is high while the gain of the other antenna is low, the reception circuit due to selection diversity usually uses only the signal from the antenna of which gain is high, therefore it is not possible to sufficiently obtain the beneficial effects of the selection diversity. The cdma 2000 1x EV-DO is disclosed in Japanese Unexamined Patent Application, First Publication No. 2002-344560.

### SUMMARY OF THE INVENTION

The present invention has been conceived in view of the above described circumstances, and its objective is to provide an antenna control method, and a wireless transmission and reception device, in which increase of the number of antennas corresponding to a plurality of frequencies is restrained, and a sufficient transmission and reception performance can be obtained.

In order to solve the above described problems, the present invention is an antenna control method for use in communication using a plurality of antennas which have different respective frequency bands, including a step in which, when performing transmission upon a predetermined frequency band out of the frequency bands, only an antenna which corresponds to the frequency band which is used is employed in a transmission system, and a step in which, when performing reception upon the predetermined frequency band, a diversity combination of the antenna which corresponds to the predetermined frequency band which is used and another antenna is employed in a reception system.

The present invention may be suitably applied to a system which uses the ratio of carrier wave to interference wave as an indicator of quality of a received signal.

Moreover, the present invention may be suitably applied to a system which uses the ratio of reception power of a desired signal to gross reception power as an indicator of quality of a received signal.

The present invention is a wireless transmission and reception device, including a plurality of antennas which have different respective frequency bands, a plurality of transmission and reception circuits which correspond to the frequency bands, a control unit in which, when performing transmission upon a predetermined frequency band out of the frequency bands, a transmission circuit of the transmission and reception circuits corresponding to the frequency band which is used connects to only a antennas which corresponds to the frequency band which is used, and, when performing reception upon the predetermined frequency band out of the frequency bands, a reception circuit of the transmission and reception circuit corresponding to the frequency band which is used connects to the antenna which corresponds to the frequency band which is used and another antenna, and a processing unit which performs diversity combination processing upon output of the reception circuit.

In the present invention, the transmission and reception circuit which corresponds to the frequency band may be provided with a plurality of reception circuits which correspond to the antennas which are connected.

In the present invention, the processing unit may measure the ratio of carrier wave to interference wave from a signal for which the diversity combination processing has been carried out.

In the present invention as described above, the processing means may measure the ratio of reception power of a desired signal to gross reception power from the signal for which the diversity combination processing has been carried out.

According to the present invention, it is possible to construct a wireless transmission and reception device which can perform transmission and reception upon a plurality of frequency bands with the minimum number of antennas, and thereby, from the point of view of number of components, cost, and size, there is the beneficial result that the decrease can be attained, as compared with the prior art in which the number of antennas is large. Furthermore, since there is no sacrifice with regard to the gain of the transmitting antenna (that is, since deterioration thereof is minimized), it is also possible to keep the deterioration of transmission output power or the increase of power consumption at the minimum possible limit. Furthermore, if a diversity combination type reception method is employed, there is the beneficial aspect that the fall of the effect of the reception diversity can be decreased.

### BRIEF DESCRIPTION OF THE DRAWINGS

FIG. 1 is a block diagram showing the structure of a portable telephone according to a first preferred embodiment of the present invention.

FIG. 2 is a block diagram showing the structure of a portable telephone according to a second preferred embodiment of the present invention.

FIG. 3 is a block diagram showing the structure of a portable telephone according to a third preferred embodiment of the present invention.

FIG. 4 is a circuit diagram showing the structure of a matching circuit of FIG. 3.

FIG. 5 is a circuit diagram showing the structure of a matching circuit of FIG. 3.

FIG. 6A is a graph showing the characteristic of an antenna of FIG. 3.

FIG. 6B is a graph showing the characteristic of that antenna of FIG. 3.

FIG. 7A is a graph showing the characteristic of an antenna of FIG. 3.

FIG. 7B is a graph showing the characteristic of that antenna of FIG. 3.

FIG. 8 is a graph showing the characteristic of an antenna of FIG. 1.

FIG. 9 is a graph showing the characteristic of an antenna of FIG. 1.

### DETAILED DESCRIPTION OF THE INVENTION

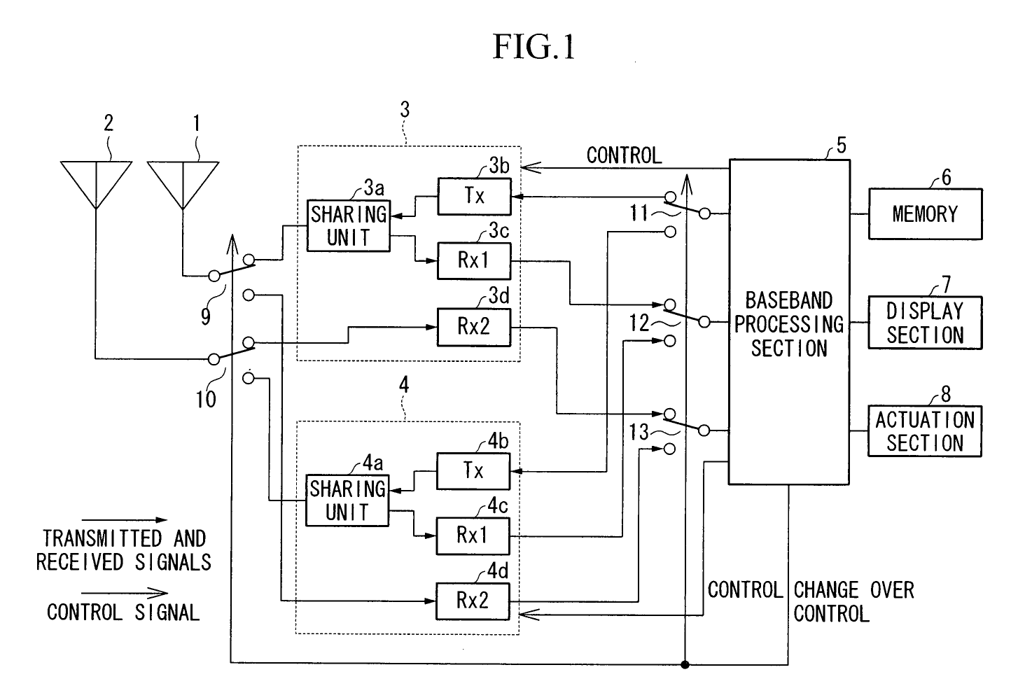

In the following, various preferred embodiments of the present invention will be explained with reference to the drawings. FIG. 1 is a block diagram showing the structure of a portable telephone unit (a wireless transmission and reception device) according to the first preferred embodiment of the present invention; the portable telephone unit shown in this figure is a portable telephone device which can perform EV-DO communication upon the 800 MHz band and EV-DO communication upon the 2 GHz band. Furthermore, the portable telephone unit performs reception processing according to a diversity method, using two antennas. In this figure, the reference symbol 1 denotes the first antenna, while the reference symbol 2 denotes the second antenna. Antennas 1 and 2 are single band antennas, and the resonant frequency of the antenna 1 is 800 MHz, while the resonant frequency of the antenna 2 is 2 GHz.

The reference symbol 3 denotes a first transmission and reception circuit which performs transmission and reception of signals on the 800 MHz band, and the first transmission and reception circuit 3 has a sharing unit 3a which shares the transmitted signal and received signal, a transmission circuit 3b which modulates a baseband signal at a high frequency of 800 MHz, a reception circuit 3c which demodulates a high frequency signal which has been received via the sharing unit 3a, and a reception circuit 3d which demodulates a high frequency signal of 800 MHz which has been received via the antenna 2. The reference symbol 4 denotes a second transmission and reception circuit which performs transmission and reception of signals on the 2 GHz band, and the second transmission and reception circuit 4 has a sharing unit 4a which shares the transmitted signal and the received signal, a transmission circuit 4b which modulates a baseband signal at a high frequency of 800 MHz, a reception circuit 4c which demodulates a high frequency signal which has been received via the sharing unit 4a, and a reception circuit 4d which demodulates a high frequency signal of 2 GHz which has been received via the antenna 1.

The reference symbol 5 denotes a baseband processing section which performs processing of the baseband signal, while 6 denotes a memory, 7 denotes a liquid crystal section, and 8 denotes an actuation section, such as a tenkey pad, or the like. The reference symbols 9 through 13 denote switches, by the operation of which change over control is performed by the baseband processing section 5. The common contact point of the switch 9 is connected to the antenna 1, and its first contact point is connected to the sharing unit 3a, while its second contact point is connected to the reception circuit 4d. The common contact point of the switch 10 is connected to the antenna 2, and the first contact point is connected to the reception circuit 3d, while the second contact point is connected to the sharing unit 4a. The common contact point of the switch 11 is connected to the baseband processing section 5, and the first contact point is connected to the transmission circuit 3b, while the second contact point is connected to the transmission circuit 4b. The common contact point of the switch 12 is connected to the baseband processing section 5, and the first contact point is connected to the reception circuit 3c, while the second contact point is connected to the reception circuit 4c. The common contact point of the switch 13 is connected to the baseband processing section 5, and the first contact point is connected to the reception circuit 3d, while the second contact point is connected to the reception circuit 4d.

With this structure, when performing EV-DO communication at 800 MHz, each common contact point of the switches 9 through 13 is connected to the first contact point of each switch. Thereby, the transmitted signal is outputted from the baseband processing section 5 via the switch 11 to the first transmission and reception circuit 3, is modulated to a high frequency signal of 800 MHz by the transmission circuit 3b of this first transmission and reception circuit 3, and is transmitted from the antenna 1. On the other hand, the high frequency received signal is received by the antennas 1 and 2, the signal which has been received by the antenna 1 is demodulated by the reception circuit 3c, the signal which has been received by the antenna 2 is demodulated by the reception circuit 3d, and the output signals of the reception circuits 3c and 3d are inputted to the baseband processing section 5 via the switches 12 and 13. The baseband processing section 5 combines the signals by a diversity combination method, and thereby generates the received signal.

Furthermore, when performing EV-DO communication at 2 GHz, each common contact point of the switches 9 through 13 is connected to the second contact point of each switch. Thereby, the transmitted signal is outputted from the baseband processing section 5 via the switch 11 to the second transmission and reception circuit 4, is modulated to a high frequency signal of 2 GHz by the transmission circuit 4b of the second transmission and reception circuit 4, and is transmitted from the antenna 2. On the other hand, the high frequency received signal is received by the antennas 1 and 2, the signal which has been received by the antenna 2 is demodulated by the reception circuit 4c, the signal which has been received by the antenna 1 is demodulated by the reception circuit 4d, and the output signals of the reception circuits 4c and 4d are inputted to the baseband processing section 5 via the switches 12 and 13. The baseband processing section 5 combines the signals by a diversity combination method, and thereby generates the received signal.

In this manner, with the above described first preferred embodiment of the present invention, the first antenna 1 and the transmission and reception circuit 3 are used at 800 MHz, while the second antenna 2 and the transmission and reception circuit 4 are used at 2 GHz. Furthermore, when performing EV-DO communication upon the 800 MHz band, the communication is performed by setting each of the switches to the side of the first contact point. In this case, the first antenna 1 is used as the main antenna for transmission and reception, while the second antenna 2 is used as a sub-antenna for reception only. In addition, the power source for the transmission and reception circuit 4 for 2 GHz is set to be OFF by control from the baseband processing section 5. Since the first antenna 1 which is the main antenna is the one which is used for 800 MHz, there is no reduction in gain (that is, increase in output transmission power or transmission electrical power consumption), while, on the other hand, since the second antenna 2 is the one which is used for 2 GHz, the sensitivity thereof to the 800 MHz signal is low. However, by the fact that a sub-antenna presents, it can be expected to provide the beneficial effect of diversity.

Furthermore, when performing EV-DO communication upon the 2 GHz band, the communication is performed by setting each switch to the side of the second contact point, the second antenna 2 is used as the main antenna, and the first antenna 1 is used as the sub-antenna. Since transmission is performed with the antenna 2 for 2 GHz, there is no deterioration of transmission gain, while, on the other hand, by the fact that the sub-antenna 1 is present although the sensitivity thereof is low, it can be expected to provide the beneficial effect of diversity combination.

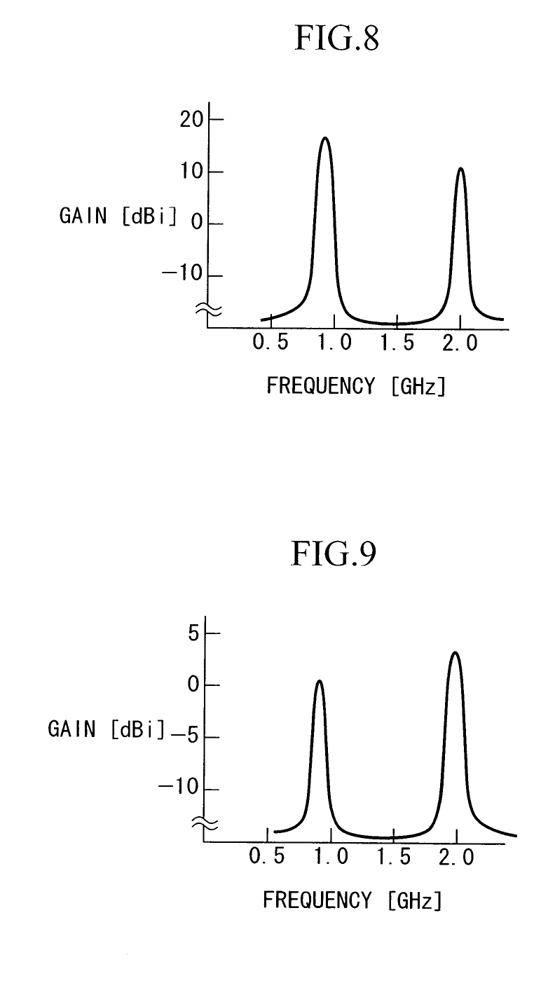

It would also be acceptable to use a dual band antenna which has individual resonance points at 800 MHz and 2 GHz as the antennas 1 and 2. In this case, the antenna which has high gain at 800 MHz is used as the first antenna 1, while the antenna which has high gain at 2 GHz is used as the second antenna 2. In this case, FIG. 8 shows the gain characteristic of the first antenna 1, while FIG. 9 shows the gain characteristic of the second antenna 2.

In this case, the gain at each resonant frequency is generally lower than in the case of a single band antenna, and moreover there is a relationship which consists of a gain tradeoff between the resonant frequencies. For example, when the gain at 800 MHz becomes high, the gain at 2 GHz becomes low, while conversely, when the gain at 800 MHz becomes low, the gain at 2 GHz becomes high. Therefore, the antenna for which “the gain at 800 MHz > the gain at 2 GHz” is used as the first antenna 1, while the antenna for which “the gain at 2 GHz > the gain at 800 MHz” is used as the second antenna, and, when performing communication at each frequency, that one of the antennas thereof for which the gain is high at that frequency is used as the main antenna, while the other antenna is used as the sub-antenna for reception only. With this type of structure, by using the antenna of which gain is high for transmission, it is possible to reduce the loss of gain (that is, increase of the output transmission power or transmission electrical power consumption) to the minimum limit, while, by the existence of the sub-antenna, it is possible to reap the benefits of a diversity combination, even though the gain thereof is lower than that of the main antenna.

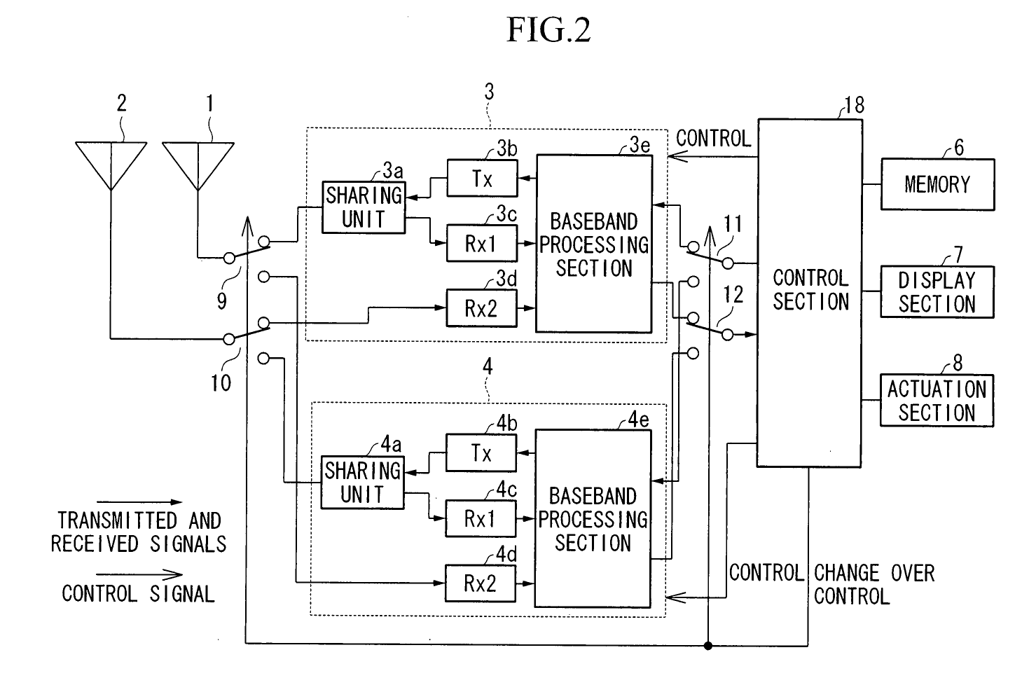

FIG. 2 is a block diagram showing the structure of a portable telephone according to the second preferred embodiment of the present invention, in this figure, to portions which correspond to portions shown in FIG. 1 and which have the same functions as those portions, the same reference symbols are affixed, and the explanation thereof will be curtailed. The portable telephone unit shown in this figure is a portable telephone unit which, for example, is compatible with the two different wireless communication methods cdma 2000 1x (800 MHz) and cdma 2000 1x EV-DO (2 GHz), the points in which the circuit thereof differs from that of the first preferred embodiment of the present invention shown in FIG. 1 are that a baseband processing section 3e for cdma 2000 1x is provided within the first reception circuit 3, while a baseband processing section for cdma 2000 1x EV-DO is provided within the second reception circuit 4, that a control section 18 which controls the various sections of the device is provided separately from the baseband processing sections 3e and 4e, and that the switch 13 is not provided.

With such a structure, when performing cdma 2000 1x communication upon the 800 MHz band, the common contact point of each switch 9 through 12 is connected to the first contact point of each switch. Furthermore, the transmitted signal is supplied from the baseband processing section 3e via the transmission circuit 3b and the sharing unit 3a to the first antenna 1, and is transmitted therefrom. On the other hand, the high frequency received signal is received by the antennas 1 and 2, and the signal which has been received by the first antenna 1 is demodulated by the reception circuit 3c, while the signal which has been received by the second antenna 2 is demodulated by the reception circuit 3d, and the signals thereof are inputted to the baseband processing section 3e.

The baseband processing section 3e generates a received signal by combining the signals by a diversity combination method, and outputs the received signal via the switch 12 to the control section 18.

On the other hand, when performing cdma 2000 1x EV-DO communication upon the 2 GHz band, the common contact point of each switche 9 through 12 is connected to the second contact point of each switch. Furthermore, the transmitted signal is outputted from the baseband processing section 4e to the transmission circuit 4b, is superimposed upon a high frequency signal of 2 GHz by the transmission circuit 4b, and then is transmitted from the second antenna 2. On the other hand, the high frequency received signal is received by the antennas 1 and 2, the signal which has been received by the second antenna 2 is demodulated by the reception circuit 4c, the signal which has been received by the first antenna 1 is demodulated by the reception circuit 4d, and the signals thereof are inputted to the baseband processing section 4e. The baseband processing section 4e generates a received signal by combining the signals by a diversity combination method, and outputs the received signal to the control section 18.

In this manner, with the above described second preferred embodiment of the present invention, during cdma 2000 1x communication, the first antenna 1 is used as a main antenna for transmission and reception, while the second antenna 2 is used as a sub-antenna for reception only. At this time, the transmission and reception circuit 3 for cdma 2000 1x is used as the transmission and reception circuit, while the power source for the transmission and reception circuit 4 for cdma 2000 1x EV-DO is set to be OFF by control from the control section 18. Since the first antenna 1 which is the main antenna is the one which is used for cdma 2000 1x, there is no reduction in gain (that is, increase in output transmission power or transmission electrical power consumption), while, on the other hand, since the second antenna 2 is the one which is used for cdma 2000 1x EV-DO, that is, for 2 GHz, by the fact that it is present as a sub-antenna although its sensitivity is low, it can be expected to provide the beneficial effect of diversity. When performing cdma 2000 1x EV-DO communication, each of the switches 9 through 12 is turned over to the side of the second contact point, and thereby the second antenna 2 is used as the main antenna, while the first antenna 1 is used as the sub-antenna. Furthermore, the power supply to the first transmission and reception circuit 3 is turned OFF by the control section 18. In addition, it would be acceptable to utilize a dual band antenna for the antennas 1 and 2, and, moreover, it would also be acceptable to utilize antennas which are provided with matching circuits, as explained in the following in connection with the third preferred embodiment.

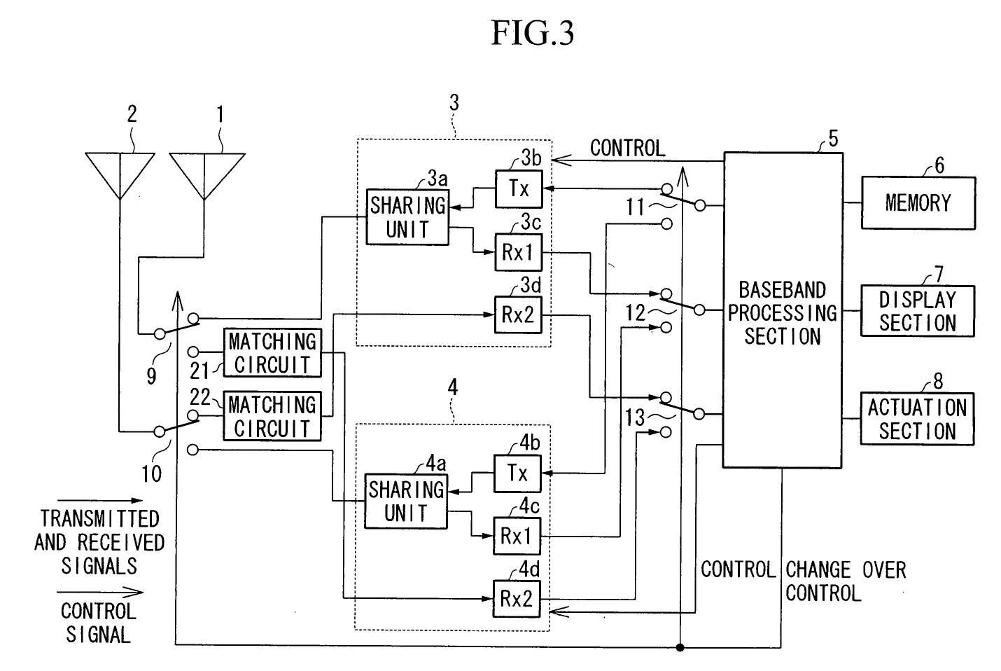

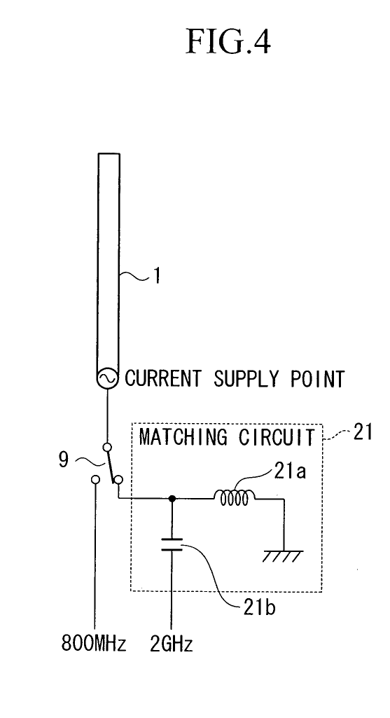

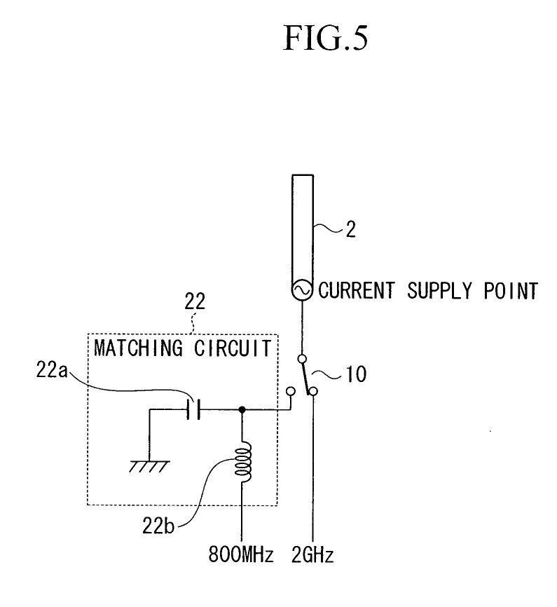

FIG. 3 is a block diagram showing the structure of a portable telephone according to the third preferred embodiment of the present invention, in this figure, to portions which correspond to portions shown in FIG. 1 and which have the same functions as those portions, the same reference symbols are affixed, and the explanation thereof will be curtailed. The portable telephone unit shown in this figure is a portable telephone unit which is capable of performing EV-DO communication upon the 800 MHz band and EV-DO communication upon the 2 GHz band, and the points in which its circuitry differs from that of the first preferred embodiment of the present invention shown in FIG. 1 are that, between the second contact point of the switch 9 and the reception circuit 4d, there is inserted a matching circuit 21 which shifts the resonant frequency of the antenna 1, and that, between the first contact point of the switch 10 and the reception circuit 3d, there is inserted a matching circuit 22 which shifts the resonant frequency of the antenna 2. FIG. 4 is an example of a circuit diagram showing the structure of the matching circuit 21, and, as shown in this figure, the matching circuit 21 is provided with a coil 21a which is interposed between the second contact point of the switch 9 and ground, and a capacitor 21b which is interposed between that the second contact point and the reception circuit 4d. Furthermore, FIG. 5 is a circuit diagram showing the structure of the matching circuit 22, and, as shown in this figure, the matching circuit 22 is provided with a capacitor 22a which is interposed between the first contact point of the switch 10 and ground, and a coil 22b which is interposed between that first contact point and the reception circuit 3d.

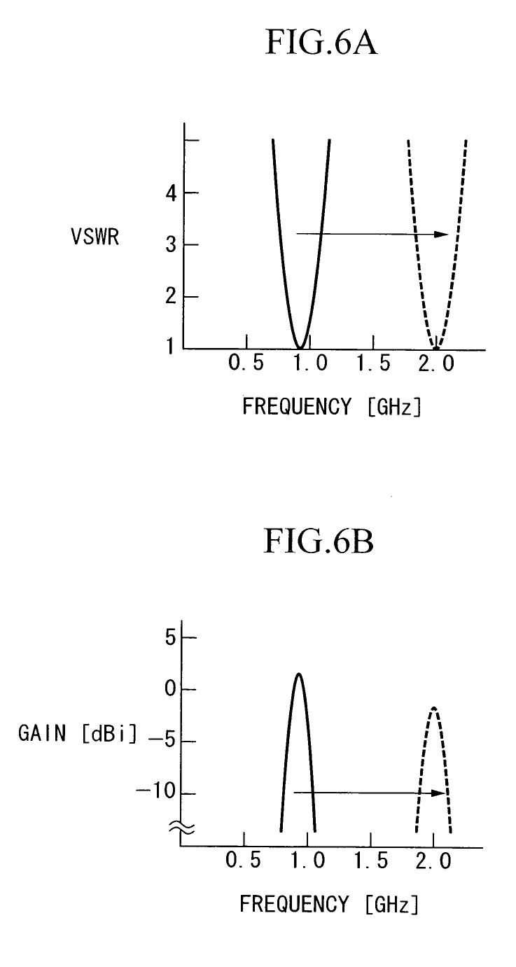

FIGS. 6A and 6B are figures showing the frequency characteristics of the first antenna 1, FIG. 6A shows the VSWR (Voltage Standing Wave Ratio) characteristic thereof, and FIG. 6B shows its gain characteristic thereof. The matching circuit 21 is not used in communication upon the 800 MHz band, and the characteristics thereof are shown by the solid lines in FIGS. 6A and 6B. On the other hand, when this device is being used at 2 GHz, the matching circuit 21 is inserted in series with the antenna 1, and thereby the characteristics are those shown by the broken lines in FIGS. 6A and 6B. At this time, the resonant frequencies of the VSWR characteristic and the gain characteristic are shifted by the matching circuit 21, but, along with the peak frequency for the gain characteristic (FIG. 6B) being shifted, a deterioration of the peak gain is also engendered, based upon the fact that it is an antenna element for 800 MHz, due to losses and the like in the matching circuit 21. Accordingly, with the first antenna 1, the gain when it is used at 800 MHz is higher than when it is used at 2 GHz.

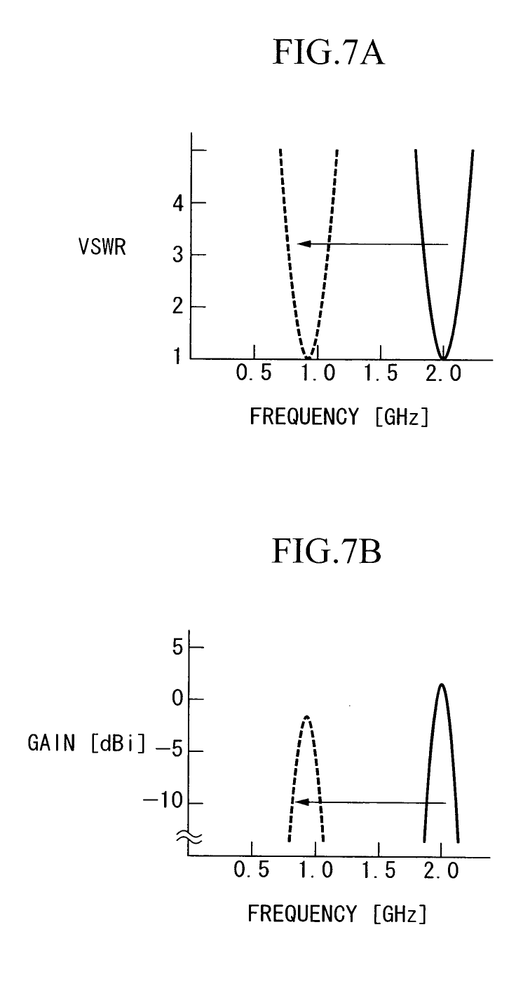

FIGS. 7A and 7B are figures showing the frequency characteristics of the second antenna 2, FIG. 7A shows the VSWR (Voltage Standing Wave Ratio) characteristic thereof, while FIG. 7B shows the gain characteristic thereof. The matching circuit 22 is provided to the second antenna 2 for 2 GHz in order to shift the resonant frequency thereof to 800 MHz, the matching circuit is not used when the second antenna 2 is being used at 2 GHz, and in this case, the characteristics thereof are those shown by the solid lines in FIGS. 7A and 7B. When this device is being used at 800 MHz, the switches are changed over under control from the baseband processing section 5, thereby the matching circuit 22 is used, and the characteristics are those shown by the broken lines in FIGS. 7A and 7B. At this time, the resonant frequency of the VSWR characteristic is shifted by the matching circuit 22, but, along with the peak frequency for the gain characteristic being shifted, a deterioration of the peak gain is also engendered due to losses, and the like in the matching circuit 22. Accordingly, with this second antenna 2, the gain when it is used at 2 GHz is higher than when it is used at 800 MHz.

By providing this type of structure, when performing communication at 800 MHz, it is possible to use the first antenna 1 for 800 MHz as the main antenna without deterioration of gain, and furthermore it is also possible to use the second antenna 2, which has been matched for 800 MHz with the matching circuit 22, as a sub-antenna as well. In this case, the gain of the sub-antenna 2 is lower than that of the main antenna 1, but it is higher than the gain of the sub-antenna in the first preferred embodiment of the present invention described above.

The above is a description of the first through the third preferred embodiments of the present invention. When performing EV-DO communication, the CIR (Carrier to Interference Ratio: the ratio of the carrier wave intensity to the interference wave intensity) is used as an indicator of the reception quality, and the DRC (Data Rate Control: an indicator of the instantaneous data rate) is determined according to the condition thereof, and is transmitted to the base station. Therefore, even if during communication, for example, the reception electrical field strength is high, if there is another base station for which the strength of reception is high, and from the point of view of the terminal thereof, there is a strong interference wave, the CIR undesirably drops, and the data rate is deteriorated. Conversely, even if the electrical field strength is low, when the level of interference waves is small, CIR becomes high, and the data rate becomes high. As a result, with an antenna of which gain is low, if the electrical field strength is above a fixed level, a high data rate can be obtained if the CIR is good, and there is a possibility of obtaining a higher CIR in conditional order of reception strength from each base station. Therefore, when performing processing according to a diversity combination method during EV-DO communication, it is possible sufficiently to obtain the beneficial effects of diversity, even if there is one of the antennas for which the gain is low.

Furthermore although, one in two antennas for the diversity in the EV-DO method, is an antenna which is not only used for reception but also for transmission, as described with regard to the deficiencies of the prior art, the gain of the transmission antenna is intimately related to the transmission output power and to the transmission electrical power which is supplied to the transmission antenna, thereby since when the gain is low, this entails deterioration of the output transmission power and increase of the consumption of electrical power, it is desirable for the gain to be as high as possible. In the above described preferred embodiments of the present invention, the gain of the antenna which is also used for transmission is made to be maximum, and moreover there is provided a reception diversity function without losing any of the beneficial effects of diversity, and thereby it is possible to provide a wireless communication terminal which is compatible with two frequency bands.

Moreover, as well as being applied to EV-DO as described above, the present invention can be also applied to the cdma 2000 1x method. Since, in the case of the cdma 2000 1x method, Ec/Io (the ratio of the total input electrical power to the energy per chip), in other words the ratio of the reception power for the desired signal to the gross reception power is used as an indicator of the quality of the received signal, it is possible to obtain the beneficial effects due to diversity combination, even if an antenna of which gain is low, unconditionally without any dependency upon the electrical field strength.

As described above, the present invention is not to be considered as being restricted simply to the intensity of the electric field, the present invention also has very beneficial effects in a system which takes as an indicator of communication quality (reception quality) an electrical power ratio, such as the ratio between the carrier wave and an interference wave, or the ratio between the reception power for the desired signal and the gross reception power, or the like.

Furthermore although, in the second preferred embodiment of the present invention described above, an example was shown of application to a combination of cdma 2000 1x (800 MHz) and cdma 2000 1x EV-DO (2 GHz), the present invention is not to be considered as being limited thereby, it would also be possible to apply the present invention to a combination of cdma 2000 1x EV-DO (800 MHz) and cdma 2000 1x EV-DO (2 GHz), or the like.

It should be understood that, although the above described preferred embodiments of the present invention are ones which utilize diversity methods with two antennas, the present invention could also be applied to a diversity transmission and reception device with three or more antennas. Furthermore, the present invention may be applied, not only to a portable telephone, but also to other types of wireless communication devices, such as a car telephone and the like.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. An antenna control method for use in communication using a plurality of antennas which have different respective frequency bands, comprising:
a step, when performing transmission upon a predetermined frequency band out of the frequency bands, employing only an antenna which corresponds to the frequency band which is used in a transmission system; and
a step, when performing reception upon the predetermined frequency band, employing a diversity combination of the antenna which corresponds to the predetermined frequency band which is used and another antenna in a reception system.

2. An antenna control method as described in claim 1, which is applied to a system which uses the ratio of carrier wave to interference wave as an indicator of quality of a received signal.

3. An antenna control method as described in claim 1, which is applied to a system which uses the ratio of reception power of a desired signal to gross reception power as an indicator of quality of a received signal.

4. A wireless transmission and reception device, comprising:
a plurality of antennas which have different respective frequency bands;
a plurality of transmission and reception circuits which correspond to the frequency bands;
a control unit wherein, when performing transmission upon a predetermined frequency band out of the frequency bands, a transmission circuit of the transmission and reception circuits corresponding to the frequency band which is used connects to only a antennas which corresponds to the frequency band which is used, and, when performing reception upon the predetermined frequency band out of the frequency bands, a reception circuit of the transmission and reception circuit corresponding to the frequency band which is used connects to the antenna which corresponds to the frequency band which is used and another antenna; and
a processing unit which performs diversity combination processing upon output of the reception circuit.

5. A wireless transmission and reception device as described in claim 4,
wherein the transmission and reception circuit which corresponds to the frequency band is provided with a plurality of reception circuits which correspond to the antennas which are connected.

6. A wireless transmission and reception device as described in claim 4,
wherein the processing unit measures the ratio of carrier wave to interference wave from a signal for which the diversity combination processing has been carried out.

7. A wireless transmission and reception device as described in claim 4,
wherein the processing means measures the ratio of reception power of a desired signal to gross reception power from the signal for which the diversity combination processing has been carried out.
